(19) United States
(12) Patent Application Publication
(10) Pub. No.: US 2010/0101644 A1
(43) Pub. Date: Apr. 29, 2010

(54) ELECTROLYTE COMPOSITION AND DYE-SENSITIZED SOLAR CELL (DSSC) COMPRISING THE SAME

(75) Inventors: Huei-Ru JHONG, Taoyuan County (TW); Hai-Peng CHENG, Taipei County (TW); Shien-Ping FENG, Hsinchu County (TW); Jo-Lin LAN, Kaohsiung City (TW); Chao PENG, Taipei County (TW); Tzu-Chien WEI, Hsinchu City (TW); Wen-Chi HSU, Tainan County (TW); Ya-Huei CHANG, Taoyuan County (TW); Wen-Hsiang CHEN, Hsinchu City (TW)

Correspondence Address: BRIAN M. MCINNIS, 12th Floor, Ruttonjee House, 11 Duddell Street, Hong Kong, HK

(73) Assignee: TRIPOD TECHNOLOGY CORPORATION, TaoYuan County (TW)

(21) Appl. No.: 12/604,413

(22) Filed: Oct. 23, 2009

Related U.S. Application Data
(63) Continuation-in-part of application No. 12/353,973, filed on Jan. 15, 2009, now abandoned.

(30) Foreign Application Priority Data
Oct. 23, 2008 (TW) 97140678
Oct. 1, 2009 (TW) 98133431

(51) Int. Cl. H01L 31/00; C09K 3/00

(52) U.S. Cl. 136/256; 252/62.2

(57) ABSTRACT

Disclosed herein is a dye-sensitized solar cell. The dye-sensitized solar cell includes a semiconductor electrode with a dye adsorbed thereon; a counter electrode; and an electrolyte composition provided between the semiconductor electrode and the counter electrode; wherein the electrolyte composition comprises an oxidation-reduction mediator and a eutectic ionic liquid including a choline halide or derivatives thereof mixed with alcohols or urea.

### RELATED APPLICATIONS

This application is a continuation-in-part of U.S. application Ser. No. 12/353,973, filed Jan. 15, 2009 which claims priority to TW Application Serial Number 97140678, filed Oct. 23, 2008. The present application also claims priority to TW Application Serial Number 98133431, filed Oct. 1, 2009. All of these applications are incorporated herein by this reference.

### BACKGROUND

1. Field of Invention

The present invention relates to an electrolyte composition and a is dye-sensitized solar cell (DSSC) comprising the same. More particularly, the present invention relates to an electrolyte composition including an ionic liquid and a DSSC comprising the electrolyte composition.

2. Description of Related Art

An electrochemical cell generally contains metal or metal oxide to serve as electrodes. An electrolyte between two electrodes carrying cations and anions functions as an internal transferring media to complete the circuit. Solar power has caught much attention as an inexhaustible energy source. The dye-sensitized solar cell is attractive for its low manufacture cost and shape flexibility; furthermore, it may generate electricity by using indoor-light sources instead of direct sun light, and is less sensitive to the incident angle compared to conventional photovoltaic. Accordingly, the dye-sensitized solar cell becomes a main research field of solar cell.

The basic structure of the dye-sensitized solar cell comprises an upper and a lower conductive glass (SnO₂: F, also known as FTO glass) layers, a conductive electrolyte, and a dye capable of being sensitized by sunlight. One of the conductive glass layers has nano scale grains of “titanium dioxide (TiO₂) semiconductor” on a surface thereof, while the other conductive glass layer has a platinum film. The conductive electrolyte and the dye are sandwiched between the two conductive glass layers; specifically, the dye is attached to the to titanium dioxide grains. As depicted in FIG. 1, the method for manufacturing the dye-sensitized solar cell comprises the following steps. First, a glass substrate 1 is provided, and a layer of transparent conducting oxide (TCO) 2 is formed over the glass substrate. An n-type semiconductor electrode 4 is then deposited on the TCO, wherein the semiconductor electrode 4 comprises TiO₂ grains 3 and a dye adsorbed on the grains and the surface. Afterward, a platinum (Pt) film 6 is coated over the glass substrate 7 as a counter electrode 5. The space contained between the upper and lower glass substrates are sealed by packaging materials 8, 11 except for an electrolyte injection inlet (not shown). Thereafter, an electrolyte 10 is injected into the space contained between the semiconductor electrode 4 and the counter electrode 5 via the electrolyte injection inlet. The operating principle of the dye-sensitized solar cell is summarized as follows. (1) After exciting by the incident photons, the electrons of the dye adsorbed on the surface of the semiconductor electrode (TiO₂) are excited from the ground state to the exciting state (S+hu→S*). (2) The excited electrons are injected into the conduction band of the semiconductor electrode and then transferred to the TCO electrode by diffusion so as to be conducted to the exterior circuit. During this stage, the dye molecules are in the oxidized state (S*→S⁺+e⁻). (3) The redox mediators (e.g. I⁻+I₃⁻) in the electrolyte react with the oxidized dye and reduce it to the ground state (S⁺+I⁻→S+I₃⁻), whereas the reductant is oxidized to I₃⁻ (4) The I₃⁻ diffuses to the counter electrode and then reduces to I⁻ the electron from the exterior circuit (I₃⁻+e⁻→I⁻). The above-described cycle may be repeated.

Practically, conventional dye-sensitized solar cells with a photoelectron conversion efficiency higher than 11% is achieved. However, highly efficient dye-sensitized solar cells utilizing volatile organic solvent (e.g. acetonitrile or 3-methoxy propionitrile) as the solvent in the electrolyte may limit the outdoor application thereof. Therefore, researchers utilize an ionic liquid as the electrolyte to manufacture a non-volatile dye-sensitized solar cell. One of the most commonly used ionic liquids of the dye-sensitized solar cell comprises imidazolium cations together with iodide ions or other anions. Nevertheless, the high viscosity of such ionic liquid may lower the photocurrent conversion efficiency and thus limit the application of such electrolyte in the solar cells.

### SUMMARY

In view of the foregoing, one aspect of the present invention is directed to an electrolyte composition comprising a eutectic ionic liquid. The electrolyte composition has low viscosity and a wide electrochemistry operation window.

Another aspect of the present invention is directed to a dye-sensitized solar cell comprising the above-mentioned electrolyte. The manufacturing process of such electrolyte is simple with low cost.

According to the first aspect, the embodiment of the present invention provides an electrolyte composition comprising a redox mediator and a eutectic ionic liquid. The eutectic ionic liquid includes a choline halide or derivatives thereof and an alcohol, or alternatively, a choline halide or derivatives thereof and a urea. Another embodiment of the present invention provides a binary ionic liquid electrolyte comprising a redox mediator, a first ionic liquid and a second ionic liquid, wherein the second ionic liquid is an imidazolium ionic liquid, and the first ionic liquid has a viscosity lower than the viscosity of the imidazolium ionic liquid.

According to the second aspect, the embodiment of the present invention provides a dye-sensitized solar cell comprising a semiconductor electrode having a dye adsorbed thereto; a counter electrode opposite to the semiconductor electrode; and an electrolyte composition injected between the semiconductor electrode and the counter electrode. The electrolyte composition comprises a redox mediator and a eutectic ionic liquid, or alternatively, a eutectic ionic liquid as a reductant of a redox mediator. The eutectic ionic liquid includes a choline halide or derivatives thereof and an alcohol, or alternatively, a choline halide or derivatives thereof and a urea.

The embodiment of the present invention also utilizes a mixture of two eutectic ionic liquids (binary ionic liquid) as the redox electrolyte of a non-volatile solar cell. The second ionic liquid used in such binary ionic liquid may be an imidazolium ionic liquid that has been commonly used.

The present invention utilizes a eutectic ionic liquid including the choline halide or derivatives thereof and alcohol, or alternatively, the choline halide or derivatives thereof and urea as the cell electrolyte to produce a dye-sensitized solar cell. Comparing with conventional electrolyte using only the imidazolium ionic liquid, the present electrolyte is simple to manufacture and exhibits good biocompatibility. In addition, the photocurrent conversion efficiency of the solar cell employing such electrolyte is acceptable.

Reference will now be made in detail to the embodiments of the invention in connection with the accompanying drawings.

It is to be understood that both the foregoing general description and the following detailed description are by examples, and are intended to provide further explanation of the invention as claimed.

### BRIEF DESCRIPTION OF THE DRAWINGS

The invention can be better understood by reading the following detailed description of the embodiments, with reference made to the accompanying drawings as follows:

FIG. 1 is a schematic diagram illustrating the basic structure of a dye-sensitized solar cell in the prior art.

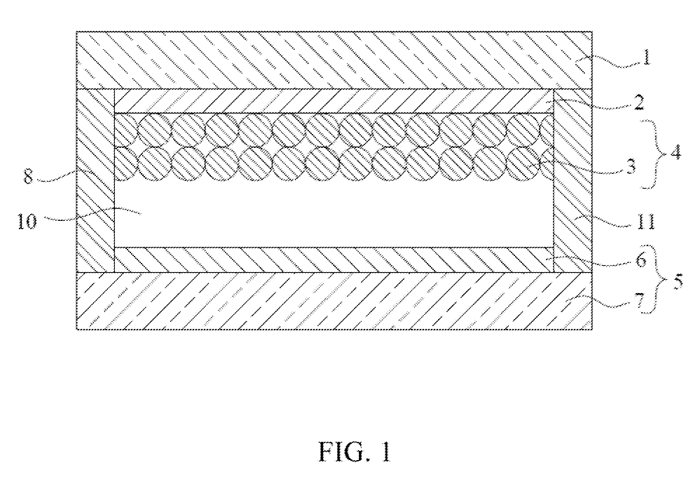

FIG. 2 is a curve diagram showing variations in melting points depending on molar ratio of glycerol, wherein the molar ratios of glycerol to butyryl choline iodide are 4:1, 3:1, 2:1, 1:1, and 1:2, respectively.

FIG. 3 is a current density-voltage characteristics diagram of a DSSC comprising the electrolyte composition according to example 6.

FIG. 4 is a current density-voltage characteristics diagram of a DSSC comprising the electrolyte composition according to example 7.

FIG. 5 is a current density-voltage characteristics diagram of a DSSC comprising the electrolyte composition according to comparative example 1.

### DETAILED DESCRIPTION

The electrolyte composition of the embodiment of the present invention for use in a dye-sensitized solar cell comprises a redox mediator, and a eutectic ionic liquid including a choline halide or derivatives thereof and an alcohol, or alternatively, a choline halide or derivatives thereof and a urea.

The dye-sensitized solar cell of the present invention comprises a semiconductor electrode having a dye adsorbed thereto; a counter electrode opposite to the semiconductor electrode; and an electrolyte composition disposed between the semiconductor electrode and the counter electrode. The electrolyte composition comprises a redox mediator and a eutectic ionic liquid, or alternatively, a eutectic ionic liquid as a reductant of a redox mediator. The eutectic ionic liquid includes a choline halide or derivatives thereof and an alcohol, or alternatively, a choline halide or derivatives thereof and a urea.

According to embodiments of the eutectic ionic liquid of the present invention, derivatives of choline halide may include but are not limited to ammonium alkyl acyl choline halide, such as ammonium formyl choline chloride, and alkyl acyl choline halide, such as butyryl choline iodide, and butyryl choline chloride. Examples of the alcohol may include but are not limited to glycerol, ethylene glycerol, and butylene glycol.

Alternatively, the electrolyte composition of the present invention may further comprise a second ionic liquid, such as an imidazolium ionic liquid commonly used. The second ionic liquid may be mixed with the eutectic ionic liquid including a choline halide or derivatives thereof and an alcohol (or the eutectic ionic liquid including a choline halide or derivatives thereof and a urea) to form a binary ionic liquid that can be used as the electrolyte of the dye-sensitized solar cell. Generally, the imidazolium ionic liquid may be 1-alkyl-3-methyl imidazolium iodide such as 1-ethyl-3-methyl imidazolium iodide, 1-hexyl-3-methyl imidazolium iodide, or 1-propyl-3-methyl imidazolium iodide.

Optionally, the electrolyte composition of the present invention may further comprise an additive such as 4-tert butyl pyridine, N-methyl benzimidazole, or guanidine thiocyanate (GuSCN). The additives may have various functions such as stabilizing the electrolyte, improving cell efficiency, avoiding unnecessary by-reaction, and extending the life span of the cell.

The redox mediator of the present electrolyte composition may be iodide/triiodide (I⁻/I₃⁻), bromine/bromide (Br₂/Br⁻), or thiocyanogen/thiocyanate (SCN)₂/SCN⁻.

The dye used in the present invention may be carboxylate polypyridyl ruthenium, phosphonate polypyridyl ruthenium, or polynuclear bipyridyl ruthenium.

Embodiments of the present invention use the eutectic ionic liquid including a choline halide or derivatives thereof and an alcohol (or the eutectic ionic liquid including a choline halide or derivatives thereof and a urea) as the cell electrolyte to manufacture dye-sensitized solar cell. Comparing with the conventional electrolyte using imidazolium ionic liquid, the dye-sensitized solar cell of the present invention exhibits acceptable photocurrent conversion efficiency.

The following examples aim to illustrate some technical features of the present invention, and are not intended to limit the scope of the present invention.

### Preparation of the Eutectic Ionic Liquids and Electrolytes

### Example 1

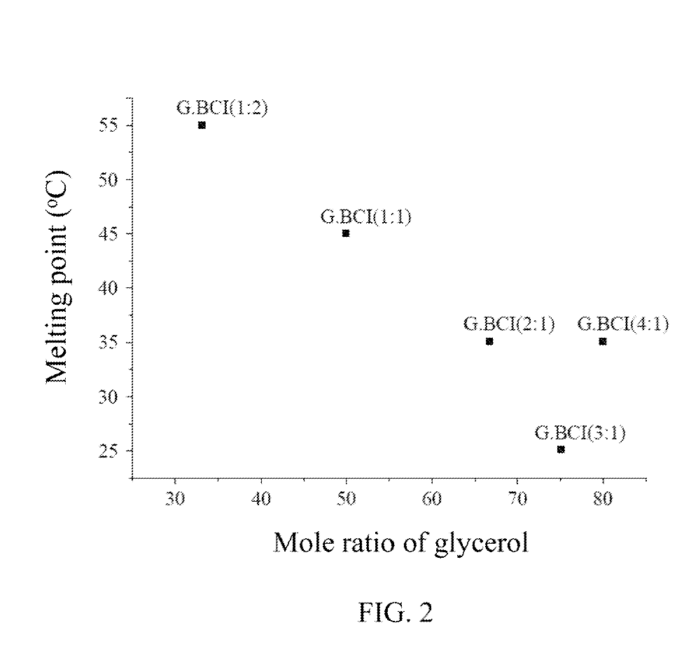

Glycerol (m.p. 18° C.) and butyrylcholine iodide (m.p. 87° C.-89° C.) were mixed in a conical flask at the mole ratio of 4:1, 3:1, 2:1, 1:1, and 1:2 respectively. The melting points of said mixtures including the glycerol (m.p. 18° C.) and the butyrylcholine iodide were evaluated by differential scanning calorimetry (DSC), and the results are shown in FIG. 2. In FIG. 2, G represents the glycerol, BCI represents the butyrylcholine iodide, and G.BCl (x:y) represents the glycerol and the butyrylcholine iodide being mixed at the mole ratio x:y. As can be seen in FIG. 2, when the glycerol and the butyrylcholine iodide were mixed at the mole ratio of 3:1, the melting point of the mixture evaluated by DSC is about 25° C. Accordingly, the preferred mole ratio of glycerol and butyrylcholine iodide ranges from about 2.5:1 to about 3.5:1.

### Examples 2-5

### Electrolytes Comprising a Eutectic Ionic Liquid and Various Additives

Glycerol and butyrylcholine iodide were mixed in a conical flask at the mole ratio of 3:1, and the mixture was heated at a temperature of 60° C. until a transparent homogeneous liquid was obtained. The transparent homogeneous liquid is a eutectic ionic liquid including butyrylcholine iodide and glycerol. The eutectic mixture thus obtained is called glycerol butyrylcholine iodide (G.BCl), and may have the structure of:

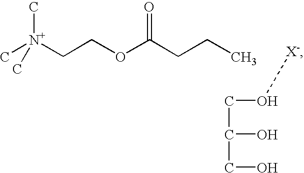

where X⁻ is I⁻.

In examples 2-5, various additives were then added into the eutectic ionic liquids of G.BCl to obtain electrolytes for use in the dye-sensitized solar cell.

Specifically, in example 2, 0.2 M of I₂ and 0.5 M of N-methyl-benzimidazole were added into the eutectic ionic liquid; in example 3, 0.5 M of NH₄I (an I⁻ source of the redox mediator) was added into the eutectic ionic liquid provided in the same manner as described in Example 2; in example to 4, 0.5 M of 1,2-dimethyl-3-propyl imidazolium (DMPII) (an 1″ source of the redox mediator) was added into the eutectic ionic liquid provided in the same manner as described in Example 2; and in example 5, 0.5 M of NH₄I and 0.5 M of 1,2-dimethyl-3-propyl imidazolium (DMPII) were added into the eutectic ionic liquid provided in the same manner as described in Example 2.

### Examples 6-7

### Binary Ionic Liquid Electrolytes

With respect to non-volatile solar cells, the viscosity of the imidazolium ionic liquid is too high so that it may decrease the cell efficiency. Accordingly, embodiments of the present invention utilize a binary ionic liquid electrolyte as redox electrolyte to form a non-volatile solar cell. Since the binary ionic liquid electrolyte may result in mass transfer effect similar to the Grotthus electron transfer mechanism, the diffusivity and/or the ion mobility thereof may not drop significantly.

Examples 6 and 7 are directed to binary ionic liquid electrolytes, where two ionic liquids respectively serve as I⁻ source of the redox mediator and solvent. In these examples, choline halides were reacted with glycerol or urea to form eutectic mixtures.

Generally, a eutectic mixture obtained by reacting glycerol with a choline halide is a glycerol choline halide (G.CX, X=halide) which has the following structure:

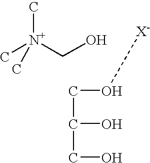

where X⁻: F⁻, Cl⁻, Br⁻, or I⁻.

Generally, a eutectic mixture obtained by reacting urea with a choline halide is a urea choline halide (U.CX, X=halide), which has the following structure:

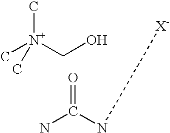

where X⁻: F⁻, Cl⁻, Br⁻, or I⁻.

In example 6, glycerol and choline chloride were mixed at the mole ratio of 2:1, and the mixture was heated at a temperature of 50° C. until a transparent homogeneous liquid was formed. The transparent homogeneous liquid is the eutectic ionic liquid including choline chloride and glycerol. The eutectic mixture thus obtained is glycerol choline chloride (G.CC).

Thereafter, I₂, 1-propyl-3-methyl imidazolium iodide (PMII, the second ionic liquid serving as I⁻ source of the redox mediator), and N-methyl benzimidazole (NMBI, additive) were added into the eutectic G.CC (the first ionic liquid serving as the solvent) to obtain the binary ionic liquid electrolyte of example 6.

In example 7, urea and choline chloride were mixed at the mole ratio of 2:1, and the mixture was heated at a temperature of 50° C. until a transparent is homogeneous liquid was formed. The transparent homogeneous liquid is the eutectic ionic liquid including choline chloride and urea. The eutectic mixture thus obtained is urea choline chloride (U.CC).

Thereafter, I₂, 1-propyl-3-methyl imidazolium iodide (PMII, the second ionic liquid serving as I⁻ source of the redox mediator), and N-methyl benzimidazole (NMBI, additive) were added into the eutectic U.CC (the first ionic liquid serving as the solvent) to obtain the binary ionic liquid electrolyte of example 7.

The composition and ratio of examples 6 and 7 are listed in Table 1. Also presented in Table 1 is the comparative example 1 that uses acetonitrile (AN) and valeronitrile (VN) as the solvents of the electrolyte, and 0.1 M of lithium iodide and 0.05 M of 4-tert-butyl pyridine (TBP) as additives of the electrolyte.

TABLE 1

| | I₃⁻ (M) | PMII (M) | Additive (M) | Solvent |
|---|---|---|---|---|
| Example 6 | 0.2 | 3.97 | 0.5 (NMBI) | G.CC |
| Example 7 | 0.2 | 3.97 | 0.5 (NMBI) | U.CC |
| Comparative | 0.05 | 0.6 | 0.1 (LiI):0.05 | AN/VN |
| example 1 | | | (TBP) | (85%:15%) |

### Examples 8-9

### Other Electrolytes

In example 8, 0.2 M of I₂ and 0.5 M of N-methyl benzimidazole (NMBI, additive) were added into the eutectic glycerol choline iodide (G.Cl) described above. In this case, eutectic ionic liquid of G.Cl (the first ionic liquid) serves as to both the I⁻ source of the redox mediator and the solvent.

In example 9, 0.2 M of I₂ and 0.5 M of N-methyl benzimidazole (NMBI, additive) were added into the eutectic glycerol butyrylcholine iodide (G.BCl) described above. In this case, eutectic ionic liquid of G.BCl (the first ionic liquid) serves as both the I⁻ source of the redox mediator and the solvent.

The composition and ratio of examples 8 and 9 are listed in Table 2. Also presented in Table 2 is the comparative example 2 that uses Michael Graetzel binary ionic liquid (1-propyl-3-methyl imidazolium iodide and tetracyanoboronic acid (PMII/EMIB(CN)₄)) as the electrolyte and the guanidine thiocyanate as the additive.

TABLE 2

| | I₃⁻ (M) | I⁻ source | Additive (M) | Solvent |
|---|---|---|---|---|
| Example 8 | 0.2 | G.CI | 0.5 (NMBI) | G.CI |
| Example 9 | 0.2 | G.BCI | 0.5 (NMBI) | G.BCI |
| Comparative | 0.2 | PMII | 0.5 (NMBI):0.1 | EMIB(CN)₄ |
| example 2 | | | (GuSCN) | |

### EXPERIMENTS AND RESULTS

### Experiment 1

### Evaluating the Efficiencies of Dye-Sensitized Solar Cells Comprising the Electrolyte Compositions of Examples 2-5

The first step in the manufacturing process of the dye-sensitized solar cell was to provide a glass substrate. Next, a layer of transparent conducting oxide (TCO) was formed on the glass substrate. Then, titanium dioxide particles were deposited on the TCO by screen-printing to form a semiconductor electrode, and the semiconductor electrode was dipped in the dye in order to make the dye molecules fully adsorbed onto the titanium dioxide particles. Next, a platinum film was plated on the other glass substrate having TCO thereon to produce a counter electrode. An electrolyte injection inlet was formed in one of the glass substrates and then the two glass substrates were sealed by packaging materials to reserve a space therebetween. Thereafter, an electrolyte was injected into the space located between the semiconductor electrode and the counter electrode via the electrolyte injection inlet.

Autolab P10 potentiostat and solar simulator (Newport) (AM1.5, 100 mW/cm²) were used to produce scanning irradiation with a scanning speed of 5 mV/sec and a scanning range starting from the open circuit voltage (Voc) to zero voltage. The current generated by the dye-sensitized solar cell was recorded to obtain the current density-voltage characteristics diagram (J-V curve) for evaluating the efficiency of the dye-sensitized solar cell. The results are listed in Table 3 where FF is the fill factor, and η is the photocurrent conversion efficiency respectively calculated according to equations (1) and (2) set forth below.

$$\begin{matrix}FF = \frac{{J}_{m} {V}_{m}}{{J}_{sc} {V}_{oc}} & ( Equation 1 ) \\ η = \frac{{J}_{m} {V}_{m}}{{P}_{s}} & ( Equation 2 )\end{matrix}$$

where,

Jₘ is the current density of maximum output power;

Vₘ is the voltage of maximum output power;

J_{sc} is the short cut current density;

V_{oc} is the open circuit voltage; and

Pₛ is the solar simulator input efficiency (i.e., 100 mW/cm²).

TABLE 3

| DSSC | | | | |
|---|---|---|---|---|
| electrolyte | J_{sc} (mA/cm²) | V_{oc} (V) | FF | η (%) |
| Example 2 | 3.3 | 0.557 | 0.624 | 1.15 |
| Example 3 | 3.86 | 0.569 | 0.663 | 1.45 |
| Example 4 | 3.53 | 0.556 | 0.645 | 1.27 |
| Example 5 | 4.32 | 0.568 | 0.652 | 1.6 |

As can be seen in table 3, the efficiency of the dye-sensitized solar cell may be improved by adding various iodide compounds into the electrolyte comprising the eutectic ionic liquid including butyrylcholine iodide and glycerol. It is believed, without being held to theory, that the cation of the iodide compound may play some roles in improving the efficiency of the dye-sensitized solar cell. For example, DMPI⁺ may be adhered onto the surface of TiO₂ nano particles and block the defect sites of the TiO₂ nano particles, which may prevent the photoelectron transferred to the TiO₂ nano particles from being trapped by triiodide (I₃⁻) within the electrolyte. In other words, DMPI⁺ may prevent the electrons at the interface of the TiO₂ nano particles and the electrolyte from refluxing, and thus may increase the current density and improve the conductivity of the electrolyte.

### Experiment 2

### Evaluating the Efficiencies of Dye-Sensitized Solar Cells Comprising the Electrolyte Compositions of Examples 6-7

The binary ionic liquids of examples 6, 7 and the electrolyte of the comparative example 1 were respectively used to manufacture the dye-sensitized solar cells. The cathode of the dye-sensitized solar cell is a transparent conducive glass electrode with platinum sputtered thereon, and the anode is a screen-printed nano/micro TiO₂ complex conductive glass electrode (thickness: 6 μm) with dye adsorbed thereon. The electrolyte is injected between the cathode and anode to accomplish the assembly of the cell.

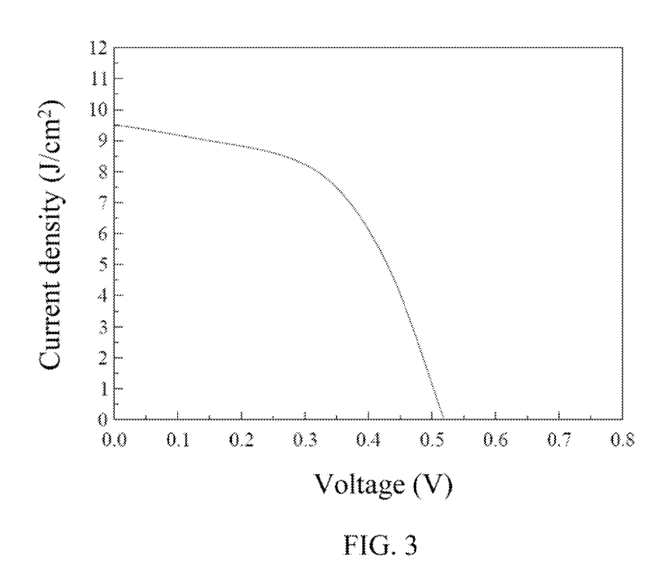

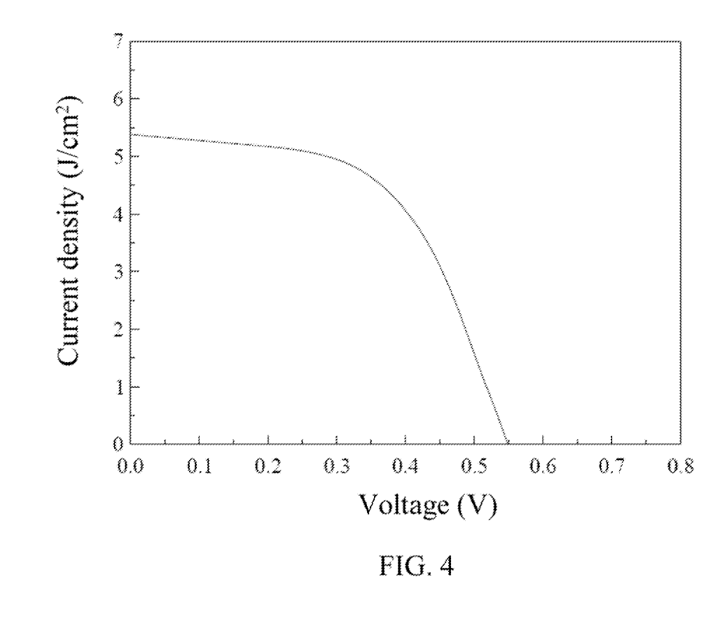

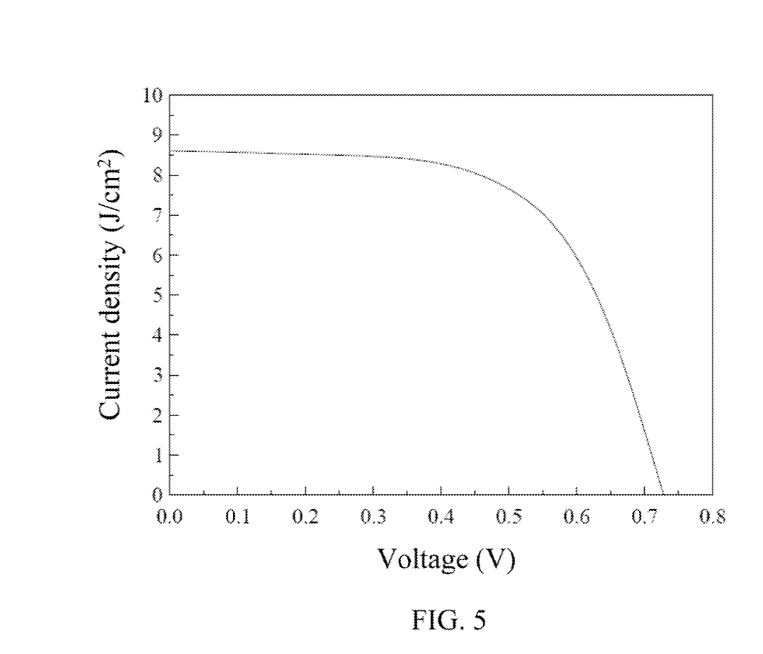

Autolab P10 potentiostat and solar simulator (Newport) (AM1.5, 100 mW/cm²) were used to produce scanning irradiation with a scanning speed of 5 mV/sec and a scanning range starting from the open circuit voltage (Voc) to zero voltage. The current generated by the dye-sensitized solar cell was recorded to obtain the current density-voltage characteristics diagram (J-V curve) for evaluating the efficiency of the dye-sensitized solar cell. The results are listed in Table 4. The J-V curves of examples 6-7 and comparative example 1 are shown in FIGS. 3-5, respectively.

TABLE 4

| Electrolyte | V_{oc} (V) | J_{sc} (mA/cm²) | FF | η_{eff} (%) |
|---|---|---|---|---|
| Example 6 | 0.52 | 9.49 | 0.53 | 2.60 |
| Example 7 | 0.54 | 5.39 | 0.56 | 1.65 |
| Comparative | 0.73 | 8.61 | 0.62 | 3.88 |
| example 1 | | | | |

It could be seen in Table 4 that the cells comprising the electrolytes of examples 6 or 7 may exhibit acceptable V_{oc} and J_{sc} value. Particularly, the photocurrent conversion efficiency of the cell of example 6 is almost the same as that of the conventional solvent type electrolyte cell (comparative example 1).

In view of the foregoing, it is appreciated that replacing conventional electrolyte solvent with the non-volatile ionic liquid with lower viscosity (e.g. G.CX or U.CX) may partially eliminate the drawbacks caused by solvent evaporation. In addition, G.CX and U.CX are recyclable and environmental-friendly. Also, during the preparation process of the electrolyte in one embodiment, no by-product would be generated and thus no additional purification step is required. The photocurrent conversion efficiency of the present cell in example 6 is also similar to those cells with conventional solvent type electrolyte. Accordingly, the electrolyte of the present invention is suitable to be applied in the dye-sensitized solar cell system.

### Experiment 3

### Comparing the Efficiencies of the Dye-Sensitized Solar Cells with Various Electrolytes Under the Same Operation Condition

In this series of experiment, the anode was dipped into the TiCl₄ solution to further increase the surface area of the TiO₂ nano particles and to optimize the eutectic ionic liquid of the present invention.

Autolab P10 potentiostat and solar simulator (Newport) (AM1.5, 100 mW/cm²) were used to produce scanning. The currents generated by the is dye-sensitized solar cell of examples 8-9 and comparative example 1 were recorded to obtain the current density-voltage characteristics diagrams (J-V curve) for evaluating the efficiencies thereof. The results are listed in Table 5.

TABLE 5

| DSSC | | | | |
|---|---|---|---|---|
| electrolyte | J_{sc} (mA/cm²) | V_{oc} (mV) | FF | η (%) |
| Example 8 | 5.01 | 630 | 0.684 | 2.15 |
| Example 9 | 7.31 | 640 | 0.642 | 3.02 |
| Comparative | 10.8 | 613 | 0.674 | 4.45 |
| example 2 | | | | |

As can be seen in table 5 that the efficiency of the dye-sensitized solar cell utilizing the eutectic ionic liquid of the present invention (including alkyl acyl choline halide and glycerol) as electrolyte is similar to that of the cell utilizing Michael Graetzel binary ionic liquid (1-propyl-3-methyl imidazolium iodide and tetracyanoboronic acid 1-ethyl-3-methyl imidazole (PMII/EMIB(CN)₄)) as electrolyte.

Hence, it is appreciated that the dye-sensitized solar cell comprising the eutectic ionic liquid electrolyte including alkyl acyl choline halide and glycerol according to one embodiment of the present invention exhibits desirable efficiency. Also, since the electrolyte of this embodiment does not include 1-propyl-3-methyl imidazolium iodide and has low water absorbability, the dye-sensitized solar cell comprising the same may be less expensive, more stable, and environmental friendly. Besides, the alkyl acyl group of the alkyl acyl choline halide may make the electron of nitrogen more delocalize, so that the iodide ion suffers less binding force, which is contributable to the increase of the electrolyte conductivity.

Furthermore, according to one embodiment of the present invention, the eutectic mixture of glycerol choline halide is used as the low viscosity ionic liquid to lower the viscosity of the imidazolium ionic liquid electrolyte. However, since the hydroxyl group of the choline halide is a water absorbent group, the preparation process should be done in a glove box, which renders the process more complicated. Hence, in one embodiment of the present invention, alkyl acyl choline halide is used to avoid this issue.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. An electrolyte composition, comprising:
a redox mediator; and
a first ionic liquid, comprising a eutectic mixture of one of a choline halide and derivatives thereof and one of an alcohol and a urea.

2. The electrolyte composition of claim 1, wherein the derivatives of the choline halide is an alkyl acyl choline halide or an ammonium alkyl acyl choline halide.

3. The electrolyte composition of claim 2, wherein the alkyl acyl choline halide is a butyryl choline halide and the alcohol is a glycerol, and the mole ratio of the butyryl choline halide to the glycerol is from about 2.5:1 to about 3.5:1.

4. The electrolyte composition of claim 1, further comprising a second ionic liquid.

5. The electrolyte composition of claim 4, wherein the second ionic liquid is an imidazolium ionic liquid.

6. The electrolyte composition of claim 5, wherein the imidazolium ionic liquid is a 1-alkyl-3-methyl imidazolium iodide.

7. The electrolyte composition of claim 1, further comprising an additive selected from the group consisting of 4-tert butyl pyridine, N-methyl benzimidazole, and guanidine thiocyanate (GuSCN).

8. The electrolyte composition of claim 1, wherein the redox mediator is selected from the group consisting of iodide/triiodide (I⁻/I₃⁻), bromine/bromide (Br₂/Br⁻) and thiocyannate/di-thiocyannate ((SCN)₂/SCN⁻) mediators.

9. A dye-sensitized solar cell, comprising:
a semiconductor electrode having a dye adsorbed onto a surface thereof;
a counter electrode opposite to the semiconductor electrode; and
an electrolyte composition, disposed between the semiconductor electrode and the counter electrode, wherein the electrolyte composition comprises a redox mediator and a first ionic liquid comprising a eutectic mixture of one of a choline halide and derivatives thereof and one of an alcohol and a urea.

10. The dye-sensitized solar cell of claim 9, wherein the derivatives of the choline halide is an alkyl acyl choline halide or an ammonium alkyl acyl choline halide.

11. The dye-sensitized solar cell of claim 10, wherein the alkyl acyl choline halide is a butyryl choline halide and the alcohol is a glycerol, and the mole ratio of the butyryl choline halide to the glycerol is from about 2.5:1 to about 3.5:1.

12. The dye-sensitized solar cell of claim 9, further comprising a second ionic liquid.

13. The dye-sensitized solar cell of claim 12, the second ionic liquid is an imidazolium ionic liquid.

14. The dye-sensitized solar cell of claim 13, wherein the imidazolium ionic liquid is a 1-alkyl-3-methyl imidazolium iodide.

15. The dye-sensitized solar cell of claim 9, further comprising an additive selected from the group consisting of 4-tert butyl pyridine, N-methyl benzimidazole, and guanidine thiocyanate (GuSCN).

16. The dye-sensitized solar cell of claim 9, wherein the redox mediator is selected from the group consisting of iodide/triiodide, (I⁻/I₃⁻), bromine/bromide (Br₂/Br⁻) and thiocyannate/di-thiocyannate ((SCN)₂/SCN⁻) mediators.

17. The dye-sensitized solar cell of claim 9, wherein the dye is a carboxylate polypyridyl ruthenium, a phosphonate polypyridyl ruthenium, or a polynuclear bipyridyl ruthenium.

18. A dye-sensitized solar cell, comprising:
a semiconductor electrode having a dye adsorbed onto a surface thereof;
a counter electrode opposite to the semiconductor electrode; and
an electrolyte composition, disposed between the semiconductor electrode and the counter electrode, comprising a eutectic ionic liquid as a reductant of a redox mediator; wherein the eutectic ionic liquid includes one of a choline halide and derivatives thereof and one of an alcohol and a urea.

19. The dye-sensitized solar cell of claim 18, wherein the derivatives of the choline halide is an alkyl acyl choline halide or an ammonium alkyl acyl choline halide.

20. The dye-sensitized solar cell of claim 19, wherein the redox mediator is selected from the group consisting of iodide/triiodide (I⁻/I₃⁻), bromine/bromide (Br₂/Br⁻), and thiocyannate/di-thiocyannate ((SCN)₂/SCN⁻) mediators.
